(19) United States
(12) Patent Application Publication
(10) Pub. No.: US 2026/0259090 A1
(43) Pub. Date: Sep. 3, 2026

(54) MECHANICAL STRESS SENSOR

(71) Applicant: Infineon Technologies AG, Neubiberg (DE)

(72) Inventors: Edwin Mario MOTZ, Wernberg (AT); Udo AUSSERLECHNER, Villach (AT); Clemens KAIN, Sankt Stefan im Rosental (AT)

(21) Appl. No.: 19/406,260

(22) Filed: Dec. 2, 2025

(30) Foreign Application Priority Data
Feb. 28, 2025 (DE) 102025107730.4

(51) Int. Cl. G01L 1/14; G01L 1/22; H10P 74/00

(52) U.S. Cl. CPC G01L 1/148; G01L 1/2293; H10P 74/277

(57) ABSTRACT

An integrated circuit includes a semiconductor substrate including a plurality of electronic components. A plurality of metal interconnect layers is stacked on the semiconductor substrate to electrically connect the electronic components together. A sensing arrangement, formed in the plurality of metal interconnect layers, is configured to provide an output signal proportional to mechanical stress applied to the integrated circuit. The sensing arrangement includes a first sensing device at least partly formed by a metal interconnect layer of the plurality of metal interconnect layers. The first sensing device is arranged to produce a change in an electronic property of the first sensing device in response to a change in mechanical stress applied to the integrated circuit. A method of manufacturing an integrated circuit includes providing a semiconductor substrate and forming a plurality of metal interconnect layers on the substrate including the sensing arrangement.

### CROSS-REFERENCE TO RELATED APPLICATION

This application claims priority to Germany Patent Application No. 102025107730.4 filed on Feb. 28, 2025, the content of which is incorporated by reference herein in its entirety.

### TECHNICAL FIELD

The present disclosure relates to a mechanical stress sensor and to a method of manufacturing the stress sensor. In particular, it relates to stress compensation for integrated circuits comprising fin field effect transistors.

### BACKGROUND

Electronic circuits are housed in packages. When a package is subjected to mechanical stress (analogously, mechanical strain), the operation of electronic components housed by the package can be affected. One potential source of mechanical stress/strain is mismatching coefficients of thermal expansion, CTE, between different package constituents (e.g., the leadframe, chip, mold compound, die attach layer, underfill and component board to which the package is soldered). Other potential sources of mechanical stress/strain include moisture ingress into the package and cure shrinkage.

Electronic components, which are positioned on a major surface of a chip (in the x-y plane), may be subjected to large in-plane normal stress components (σₓₓ, σ_{yy}). Some parameters of circuit components vary with mechanical stress: for example, the sheet resistance of resistors (including diffused, implanted, sputter or deposited resistors) may vary with in-plane mechanical stress, likewise conduction mobility, Hall mobility, saturation current and transconductance of metal-oxide-semiconductor field-effect transistors (MOSFETs), may vary as a result of being subject to mechanical stress. This may affect circuit performance.

The effect of stress-dependent circuit performance can be mitigated by implementing stress compensation circuits to counteract the effect of mechanical stress. The stress sensors used in stress compensation circuits typically involve the use of multiple different electronic devices whose parameters respond differently to mechanical stress. The in-plane normal stress components (σₓₓ, σ_{yy}) can be derived by comparing the different responses of the different electronic devices, and this information can be used to provide stress compensation.

It would be desirable to provide a stress sensor for sensing mechanical stress applied to an integrated circuit and its components that can be conveniently manufactured. Further, it would be desirable to provide on-chip stress sensors compatible with various technologies.

### SUMMARY

Examples disclosed herein propose an integrated circuit including a plurality of electronic components and a sensing arrangement adapted to provide an output signal including a component proportional to the mechanical stress applied to the integrated circuit.

A plurality of metal interconnect layers is stacked on the semiconductor substrate. The plurality of metal interconnect layers electrically connect the electronic components together. The sensing arrangement is formed in the plurality of metal interconnect layers.

The sensing arrangement includes a first sensing device at least partly formed by a metal interconnect layer of the plurality of metal interconnect layers. The first sensing device is arranged to produce a change in an electronic property of the first sensing device in response to a change in mechanical stress applied to the integrated circuit.

A method of manufacturing an integrated circuit includes providing a semiconductor substrate and forming a plurality of metal interconnect layers on the substrate including a first metal interconnect layer. Forming the plurality of metal interconnect layers includes forming a sensing arrangement adapted to provide an output signal including a component proportional to a change in mechanical stress applied to the integrated circuit.

Forming the sensing arrangement includes forming a first sensing device in the first metal interconnect layer. The first sensing device is arranged to produce a change in an electronic property of the first sensing device in response to a change in mechanical stress applied to the integrated circuit.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 is a schematic diagram of an integrated circuit, in a cross sectional view, according to examples described herein;

FIG. 2 is a plan view of an example sensing device;

FIG. 3 is a cross sectional view of an integrated circuit, having the same general structure as the integrated circuit FIG. 1, wherein the cross section is taken through the y-z plane;

FIG. 4 is a highly schematic diagram of an integrated circuit, in a cross sectional view, according to examples described herein;

FIG. 5 is a cross sectional view of the integrated circuit of FIG. 4;

FIG. 6 is a cross sectional view of the integrated circuit of FIG. 4 and FIG. 5;

FIG. 7 illustrates an example of a sensing device;

FIG. 8 illustrates another example of an integrated circuit;

FIG. 9 is a cross sectional view of FIG. 8;

FIG. 10 illustrates a sensing arrangement for deriving the difference (σₓₓ−σ_{yy}) between the two in-plane normal mechanical stress components;

FIG. 11 illustrates another sensing arrangement for deriving the difference (σₓₓ−σ_{yy}) between the two in-plane normal mechanical stress components;

FIG. 12 illustrates a sensing device for use in an example sensing arrangement;

FIG. 13 shows an evaluation circuit adapted to derive the difference between the in-plane normal mechanical stress components (σₓₓ−σ_{yy}) for the sensing arrangement of FIG. 8;

FIG. 14 shows an example of a sensing arrangement and an example evaluation circuit;

FIG. 15 shows an example of a sensing arrangement and an example evaluation circuit;

FIG. 16 shows an example of a sensing arrangement and an example evaluation circuit;

FIG. 17 shows an example of a sensing arrangement and an example evaluation circuit;

FIG. 18 shows an example of a sensing arrangement and an example evaluation circuit;

FIG. 19 shows an example of a sensing arrangement and an example evaluation circuit;

FIG. 20 shows an example of a sensing arrangement and an example evaluation circuit;

FIG. 21 shows an example of a sensing arrangement and an example evaluation circuit;

FIG. 22 shows an example of a sensing arrangement and an example evaluation circuit;

FIG. 23 is a schematic diagram illustrating the operation of an integrated circuit comprising a stress compensation circuit; and

FIG. 24 is a flow diagram illustrating a method of fabricating an integrated circuit according to examples disclosed herein.

### DETAILED DESCRIPTION

The examples described herein provide an integrated circuit. The integrated circuit comprises a semiconductor substrate comprising a plurality of electronic components. A plurality of metal interconnect layers is stacked on the semiconductor substrate, wherein the plurality of metal interconnect layers electrically connect the electronic components together. The plurality of metal interconnect layers may be electrically isolated from the semiconductor substrate, for example by dielectric material (such as nitrides and/or oxides).

The integrated circuit further comprises a sensing arrangement adapted to provide an output signal. The output signal has a property that varies with mechanical stress applied to the integrated circuit. More specifically, it comprises a component proportional to mechanical stress applied to the integrated circuit. The sensing arrangement is formed in the plurality of metal interconnect layers.

The sensing arrangement comprises a first sensing device at least partly formed by one of the plurality of metal interconnect layers. The first sensing device is arranged to produce a change in an electronic property of the first sensing device in response to a change in mechanical stress applied to the integrated circuit.

It will be appreciated that mechanical stress is related to mechanical strain. Accordingly, the output signal can be used to derive mechanical strain information. That is, the sensing arrangement can be used to sense mechanical strain applied to the integrated circuit.

The first sensing device is at least partly formed by one of the metal interconnect layers stacked on the substrate surface such that an output of the first sensing device is predominantly due to the part of the first sensing device formed from the metal interconnect layer.

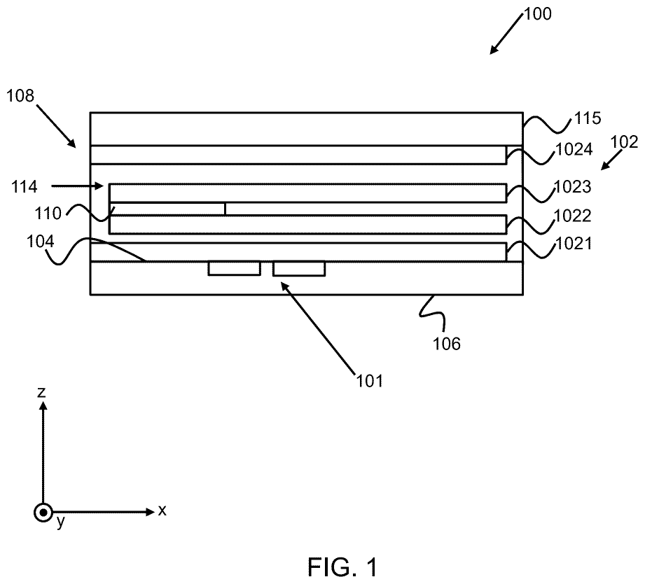

FIG. 1 illustrates an example of an integrated circuit 100 comprising a plurality of metal interconnect layers 102 stacked on an upper surface 104 of a substrate 106 and a sensing arrangement 108 formed in the plurality of metal interconnect layers 102. The sensing arrangement 108 is adapted to output a signal having a property that varies with mechanical stress applied to the integrated circuit 100. The integrated circuit 100 comprises a plurality of electronic components 101 formed in and/or on the substrate 106.

In general, in an integrated circuit, the metal layers experience approximately the same strain components as the substrate. It is therefore possible to derive information about the stress applied to the electronic components using stress sensors formed in the metal interconnect layers stacked on the substrate.

The substrate 106 comprises a semiconductor material: for example, the substrate 106 may comprise silicon. The integrated circuit 100 comprises a first metal interconnect layer 1021, a second metal interconnect layer 1022, a third metal interconnect layer 1023 and a fourth metal interconnect layer 1024. The metal interconnect layers are stacked in a direction orthogonal to the plane of the upper surface 104 of the substrate 106. As shown in FIG. 1, the upper surface 104 of the substrate extends in the x-y plane, and the plurality of metal interconnect layers are stacked on the upper surface 104 along the z-direction.

In the integrated circuit 100, neighboring metal interconnect layers are electrically connected in the z-direction by a corresponding via extending between the two neighboring metal interconnect layers. The metal interconnect layer most proximate to the substrate (the first metal interconnect layer 1021) is electrically connected to its neighboring metal interconnect layer (the second metal interconnect layer 1022) by a first via (not shown). The second metal interconnect layer 1022 connected to the third metal interconnect layer 1023 by a second via 110. The third metal interconnect layer 1023 is connected to the fourth metal interconnect layer 1024 by a third via (not shown).

The metal interconnect layers 102 may be formed of pure metal or they may comprise metal alloys or metal blended with silicon e.g., AlSiCu. The vias comprise different material to the material of the metal interconnect layers. For example, the vias may comprise tungsten, whereas the metal interconnect layers 102 may comprise aluminum or a copper alloy.

Dielectric insulating layers 114 are provided between the metal interconnect layers 102. The dielectric insulating layers 114 may comprise various materials including phosphosilicate glass oxide, undoped silicate glass oxide, nitrides and/or Silicon carbide. Diffusion barriers (e.g., titanium diffusion barriers) may additionally be provided between the metal interconnect layers 102. The integrated circuit 100 may comprise one or multiple polysilicon layers between the substrate 106 and the first metal interconnect layer 1021. Polysilicon layers may additionally be provided between each set of neighboring metal interconnect layers.

A polyamid coating layer 115 is stacked on top of the metal interconnect layers 102.

As previously mentioned, the sensing arrangement 108 is formed in the plurality of metal interconnect layers 102. The sensing arrangement 108 may be formed in a single metal interconnect layer or it may be formed in multiple metal interconnect layers. In some examples each or some of the metal interconnect layers may comprise the same material as the other metal interconnect layers.

The sensing arrangement 108 comprises a first sensing device aligned along a first direction. The first sensing device is formed within the metal interconnect layers 102—that is, the first sensing device is formed by at least one of the metal interconnect layers. The fabrication process for forming the integrated circuit therefore involves forming the first sensing device during deposition of the metal interconnect layers. This may facilitate efficient integration of the sensing arrangement.

Implementing the first sensing device within one or more metal interconnect layers allows providing stress sensing functionality for semiconductor technologies in which the implementation of conventional stress sensors directly in the semiconductor substrate using metal-oxide-semiconductor field-effect transistors (MOSFETs) or resistors (implanted or diffused) is limited or blocked. For example, in fin field effect transistor (Fin-FET) technologies, MOSFETs and implanted or diffused resistors are restricted by design rules and are not allowed to be rotated by 90°. However, to implement conventional stress sensors in semiconductor substrates, an arrangement of MOSFETs or resistors in at least two orthogonal directions is required. Examples disclosed herein overcome the limitations provided by such semiconductor technologies by implementing the stress sensing arrangement in the metal interconnect layers. Design rules allow the wires formed in the metal interconnect layers to extend in orthogonal directions. Furthermore, even though the sensing device is not formed in the semiconductor substrate, the sensing device formed in one or more of the metal interconnect layers allows a measurement of the stress within the semiconductor substrate due to the following. The metal interconnect layers and the interstitial dielectric isolation layers (which together are sometimes also referred to as back-end of line (BEOL) layers) are in the range of a few hundred nanometers (e.g., 350 nm for current CMOS technologies) while the substrate is in the range of a few hundred micrometers (e.g., 200 μm for current CMOS technologies). Accordingly, the semiconductor substrate is much stiffer than the plurality of thin BEOL layers. Therefore, a sensing device arranged in one or more of the metal interconnect layers does not directly interact mechanically with the semiconductor substrate. However, strain appearing in the semiconductor substrate is forced onto the much thinner BEOL layers. The strain of the semiconductor substrate causes therefore a change of a property of the first sensing device such as a change in resistance, capacitance or time-constants as will be outlined below in more detail.

The examples described herein are distinguished from conventional stress sensors (stress sensors based on MOSFETs or implanted/diffused resistors) which are arranged within the substrate for which the stress is to be determined, e.g., within the semiconductor substrate comprising the electronic components (e.g., transistors, doped semiconductor resistors etc.) affected by the mechanical stress. Conventional stress sensors may obtain a higher signal amplitude but they are also affected by a larger process variation. Examples described herein follow a different approach in which the stress sensing device for measuring the mechanical stress in the semiconductor substrate is not implemented in the same substrate, e.g., the semiconductor substrate, but within one or more layers outside of the semiconductor substrate, e.g., in the metal interconnect layers provided above the semiconductor substrate. The first stress sensing device and other stress sensing devices disclosed herein are nevertheless capable of measuring the mechanical stress in the substrate and are therefore capable of compensating for mechanical stress effects affecting electronic components that are located in the semiconductor substrate as will be outlined below.

The first sensing device is adapted to output a signal having a property that varies as a function of mechanical stress. Mechanical stress acting on the semiconductor substrate can therefore be determined based on the output signal of the first sensing device. For example, the amplitude or the frequency of the signal may vary as a function of mechanical stress. At least a component of the signal is proportional to mechanical stress. That is, the property of the signal varies with mechanical stress and may include an offset.

In some examples, the first sensing device comprises a resistor aligned along the first direction (that is, the resistor is arranged such that current conducted by the first sensing device flows predominantly in the first direction). The resistor is a metal resistor formed in at least one of the plurality of metal interconnect layers. For example, a resistor aligned along a direction in the plane of the substrate 106 (e.g., the x-direction or the y-direction) is formed by a single metal interconnect layer. In this case, the resistance of the resistor is predominantly the resistance of the metal portion of the interconnect metal layer forming the resistor. A resistor aligned along an out-of-plane direction (e.g., the z-direction) may be formed from at least two neighboring metal interconnect layers and at least one via connecting the neighboring metal interconnect layers. In this case, the resistance of the resistor is predominantly the resistance of the metal portion of the at least one via. In these examples, the first sensing device senses the mechanical stress based on changes of the resistance of the resistors responsive to mechanical stress.

As the resistor is a pure metal resistor, the resistance of the resistor is mainly sensitive to geometrical deformations with only a small piezo-resistive contribution. Accordingly a pure geometrical deformation of the metal in response to mechanical stress causes a change of the resistance with a smaller contribution of a piezo-resistive action in response to mechanical stress. The changes of the resistance of the resistor responsive to mechanical stress may be small in the order of 1% per GPa (Giga Pascal). However, since the response to mechanical stress is dominated by pure geometrical deformations, the process spread of the resistor formed in the metal interconnect layers is also small. Accordingly, the resistors formed in metal interconnect layers can be used in the stress sensing devices disclosed herein to provide a suitable mechanical stress sensing.

In some other examples, the first sensing device comprises a capacitor aligned along the first direction (that is, the capacitor is arranged such that the electric field between the capacitor's electrodes is orientated along the first direction). The capacitor is formed in at least one of the plurality of metal interconnect layers. For example, a capacitor aligned along a direction in the plane of the substrate 106 (e.g., the x-direction or the y-direction) is a lateral capacitor formed by a single metal interconnect layer. A capacitor aligned along an out-of-plane direction (e.g., the z-direction) may be formed from at least two different metal interconnect layers. The metal plates of the capacitor are formed one over the other. The metal plates are charged with a same amount of charges but different polarity such that the resulting electric field between the metal plates has for the lateral capacitor a predominantly lateral direction and for the vertical capacitor a predominantly vertical direction.

In this example, the first sensing device senses the mechanical stress based on changes of the capacitance of the capacitor responsive to mechanical stress. The capacitance of the capacitor is sensitive to geometrical deformations. Accordingly a pure geometrical deformation of the metal plates of the capacitor in response to mechanical stress causes a change of the capacitance. In addition thereto, a change of the dielectric constant εᵣ between the metal plates of the capacitor may add to the pure geometrical deformation to cause a smaller change of the capacitance of the capacitor in response to mechanical stress. The changes of the capacitance of the capacitor responsive to mechanical stress may be small in the order of 1% per GPa (Giga Pascal). However, although the changes are small, the process spread of the capacitor formed in the metal interconnect layers is also small. While the signals obtained by a conventional stress sensor (using MOSFETs or implanted/diffused resistors) formed within the semiconductor substrate may be higher, also the process variations are in such conventional stress sensors higher compared to implementing the stress sensing device as explained herein. Therefore, capacitors formed in metal interconnect layers can be suitable for mechanical stress sensing by the stress sensing devices disclosed herein.

In some further examples, the first sensing device comprises a resistor-capacitor (RC) circuit comprising at least one capacitor and at least one resistor. The at least one capacitor and the at least one resistor may be formed in the same metal interconnect layer. Alternatively, the capacitor and the resistor may be formed in different metal interconnect layers.

Providing a sensing device sensitive to mechanical stress formed in at least one of the plurality of metal interconnect layers stacked on the substrate of an integrated circuit may facilitate simple and cost-effective manufacturing of the integrated circuit. Such a sensing device may be provided in combination with e.g., Complementary Metal-Oxide (CMOS) stress-sensing devices as a diverse or redundant stress sensor.

In examples in which the integrated circuit comprises multiple sensing devices formed in at least one of the plurality of metal interconnect layers stacked on the substrate of an integrated circuit, the sensing devices being aligned in different directions so as to respond differently to the stress components can be used to derive information about different stress components. For example the sensing devices can be used to derive information about the in-plane normal stress components of mechanical stress applied to the integrated circuit, as will now be explained in further detail.

In some examples, the sensing arrangement comprises a second sensing device aligned along a second direction substantially perpendicular to the first direction (that is, the first direction and the second direction subtend an angle of equal to or greater than 70 to equal to or less than 110 degrees). Because the first sensing device and the second sensing device are aligned in different directions, they respond differently to the stress components of mechanical stress applied to the integrated circuit (for example the in-plane normal stress components).

In some examples, the sensing arrangement is configured to measure stress that is introduced by a semiconductor package. Typically, the dominant stress components introduced by conventional semiconductor packages are in-plane components, e.g., σₓₓ, σ_{yy}, or σ_{xy}. Except for edge regions, σₓₓ, σ_{yy} is dominant over σ_{xy}. For most semiconductor device applications, the sensing arrangement may therefore be provided for measuring the σₓₓ and σ_{yy} components. However, in some applications, for example magnetic angle sensors, the sensing arrangement may be configured to measure also the σ_{xy} component as the effect of the small σ_{xy} component on the specific application (e.g., magnetic angle sensing) can be huge.

The integrated circuit further comprises an integrated evaluation circuit configured to compare the response of the first sensing device to a change in mechanical stress applied to the integrated circuit with the response of the second sensing device to a change in mechanical stress applied to the integrated circuit. That is, the evaluation circuit compares the change in a stress-dependent electronic property of each of the first and second sensing devices. Because the sensing devices are formed as part of the metal interconnect layers, the evaluation circuit can be conveniently monolithically formed with the sensing devices.

The first sensing device and the second sensing device may be resistors, wherein the first sensing device is aligned along the x-direction and the second sensing device is aligned along the y-direction. By comparing the resistance of the first sensing device and the second sensing device (for example, by taking the ratio of Rx to Ry), it is possible to derive the difference (σₓₓ−σ_{yy}) between the two in-plane normal mechanical stress components.

In another example, the first sensing device and the second sensing device are capacitors, and the capacitance of the two sensing devices is compared to derive the difference (σₓₓ−σ_{yy}) between the two in-plane mechanical stress components.

In another example, the first sensing device and the second sensing device each comprise a resistor-capacitor (RC) circuit. By comparing the RC time constant of the first sensing device and the RC time constant of the second sensing device it is possible to derive the difference (σₓₓ−σ_{yy}) between the two in-plane mechanical stress components.

The sensing arrangement 108 may further comprise a third sensing device aligned along a third direction. As a result of the relationship between stress in the substrate close to the surface (where electronic components are formed) and strain in metal interconnect lines above the substrate surface, it is possible to derive values for the normal in-plane stress components at the integrated circuit's substrate using sensing devices formed in the metal interconnect layers. Accordingly, the third sensing device can be used, together with the first and second sensing devices, to derive individual values for the in-plane normal stress components σₓₓ, σ_{yy}. That information can be used to carry out stress compensation for the electronic components of the integrated circuit.

Stress compensation carried out with respect to an electronic component reduces the effect of mechanical stress on the circuit of the electronic component's circuit (e.g., a bandgap voltage reference circuit, an oscillator circuit or a Hall effect sensor circuit). For example, the amount by which a parameter of the electronic component circuit varies with an in-plane stress component may be known. Stress compensation may therefore involve measuring the in-plane normal stress components and actively compensating the parameter based on the measured stress to enhance the circuit's resilience to mechanical stress.

As an example, the electronic component may be a relaxation oscillator that generates a current that charges and discharges a capacitor repetitively. The relaxation oscillator has an output frequency: one period of the frequency is the time it takes to charge and discharge the capacitor. The current is generated by applying a voltage over a resistor. If stress acts on the resistor, its resistance changes. Depending on the resistor and the stress component, the resistance may for example decrease which increases the current. This, in turn, the oscillator frequency is increased. A change in stress of 100 MPa may be known to increase the oscillator frequency by 5%. Stress compensation (which may be implemented by an appropriate circuit) involves measuring the change in stress and, depending on the measured stress, actively reducing the charging/discharging current by 50%/GPa. In this way, the stress compensation improves the stability of the oscillator frequency to mechanical stress. In other examples, depending on the resistor and the stress component, the resistance may for example increase which decreases the current.

Parameters of electronic components may vary differently in response to different in-plane normal stress components. Obtaining individual values for the in-plane normal stress components may therefore facilitate accurate stress compensation.

In some examples, each of the first, second and third sensing devices may be the same type of sensing device (each sensing device may be a resistor, or each sensing device may be a capacitor or each sensing device may be an RC circuit). In some other examples, at least two of the first, second and third sensing devices are different types of sensing device.

Further examples of integrated circuits and sensing devices suitable for use in the integrated circuits described in this application will now be described.

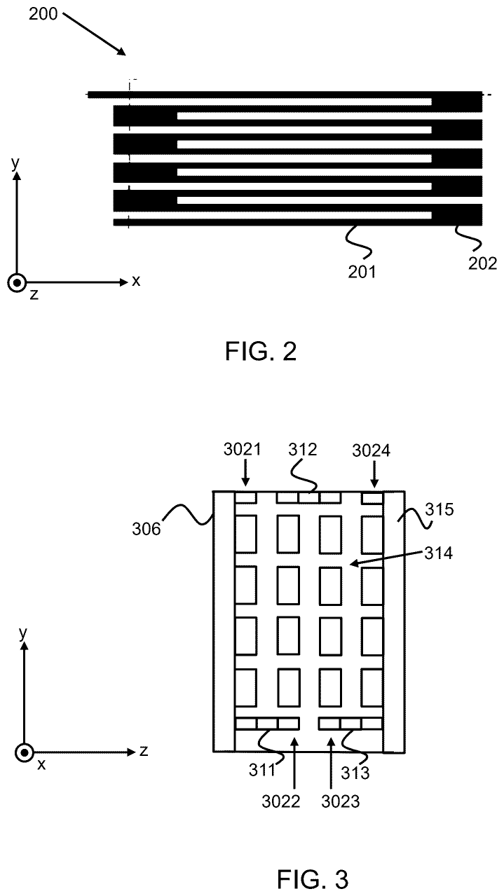

FIG. 2 illustrates an example of a sensing device formed in a metal interconnect layer. The sensing device illustrated in FIG. 2 is a resistor 200. The resistor 200 is formed in a meander pattern: it comprises multiple legs 201 extending in the x-direction, wherein neighboring legs are connected by relatively wide connection 202 portions extending along the y-direction. This configuration ensures that current flow in the y-direction is negligible compared to current flow in the x-direction. A resistor aligned in the y-direction is provided by rotating the pattern by 90 degrees, such that the legs extend in the y-direction and the relatively wide portions connection neighboring legs extend along the x-direction.

FIG. 3 illustrates an example integrated circuit 300 comprising four sensing devices formed in the plurality of metal interconnect layers 302. The integrated circuit 300 of FIG. 3 has the same general structure as the integrated circuit described in connection with FIG. 1. A plurality of metal interconnect layers is stacked on a substrate 306. Dielectric layers 314 are provided between the substrate 306, the metal interconnect layers and a polyamide coating 315.

In FIG. 3, the integrated circuit 300 comprises four sensing devices, each in the shape of the meander pattern shown in FIG. 2, aligned along the x-direction. A first sensing device is formed entirely by the first metal interconnect layer 3021 and a second sensing device is formed entirely by the second metal interconnect layer 3022. The first and second metal interconnect layers are connected by a first via 311. Likewise, a third sensing device is formed entirely by the third metal interconnect layer 3023 and a fourth sensing device is formed entirely by the fourth metal interconnect layer 3024. The second and third metal interconnect layers are connected by a second via 312, while the third and fourth metal interconnect layers are connected by a third via 313.

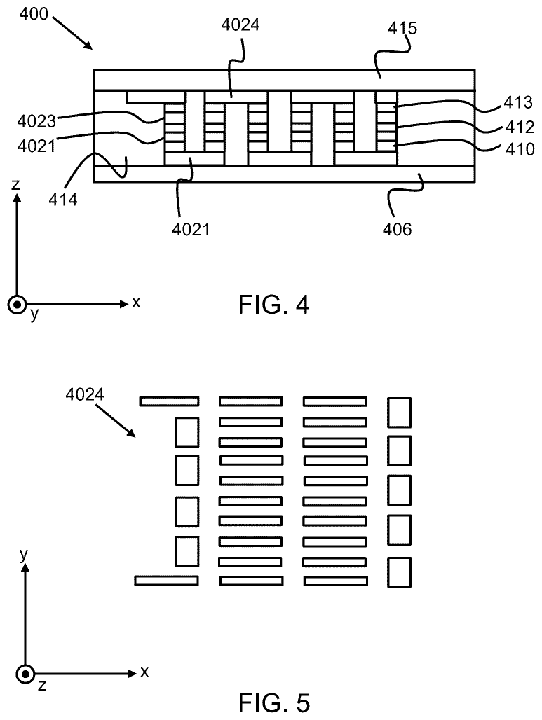

FIG. 4 illustrates an integrated circuit 400 in which a resistor, formed in a plurality of metal interconnect layers of the integrated circuit 400, is aligned along a third direction (the z-direction), substantially orthogonal to the substrate 406 of the integrated circuit 400. The integrated circuit 400 of FIG. 4 has the same general structure as the integrated circuit 100 described in connection with FIG. 1. The plurality of metal interconnect layers is stacked on the substrate 406. Dielectric layers 414 are provided between the substrate 406, the metal interconnect layers and a coating 415, comprising for example polyamide. A resistor 401 is formed from multiple metal interconnect layers and multiple vias 410, 412, 413. Each via may connect a portion of one metal interconnect layer to a portion of a metal interconnect layer below and/or above the one metal interconnect layer. For example, in FIG. 4 the via 413 connects a portion of an upper metal interconnect layer 4024 to a portion of an interconnect layer 4023 below the upper metal interconnect layer 4024. The via 412 connects the portion of the metal interconnect layer 4023 to a portion of an interconnect layer 4022 below the metal interconnect layer 4023. The via 410 connects the portion of the metal interconnect layer 4022 to a lowest interconnect layer 4021 below the metal interconnect layer 4022. The lowest interconnect layer may be isolated against the substrate 406 using a further dielectric layer (not shown). The resistor 400 is adapted so that, in use, the major component of current flows along the z-direction.

FIG. 5 illustrates a plan view of the metal interconnect layer 4024 of the integrated circuit of FIG. 4. As shown by FIG. 4 and FIG. 5, the resistor is formed as a two-fold meander (it has the shape of a meander in both the x-y plane and the x-z plane). In other examples, the resistor could be formed as a three-fold meander. The shape of the resistor is adapted to maximize the proportion of current flow along the z-direction.

If the resistor is pulled in the x-direction, the vias and metal interconnect layers widen in the x-direction and narrow in the y-direction (according to the Poisson ratio). The increase in the x-direction dominates. The vias and metal interconnect layers also narrow along the z-direction. The overall effect is a reduction in resistance. If the vias and portions of the resistor formed by the second metal interconnect layer and the third metal interconnect layer are square-shaped, the resistor behaves identically under stress in the x-direction and the y-direction. The resistor's stress-dependence is therefore proportional to the sum of the in-plane normal stress component in the x-direction and the in-plane normal stress component in the y-direction.

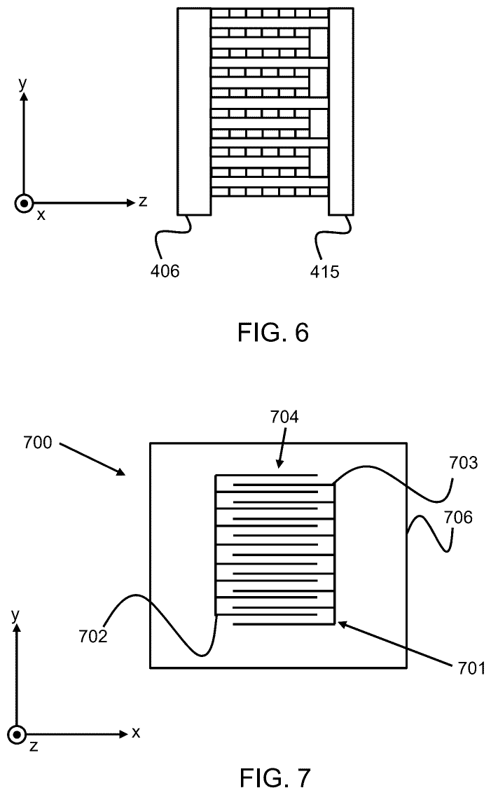

FIG. 6 illustrates a cross-sectional view of the integrated circuit of FIG. 4, in the y-z plane.

As discussed above, it is possible to derive values for each of the normal components of in-plane stress (σₓₓ, σ_{yy}) using three sensing devices formed in the plurality of metal interconnect layers stacked on the integrated circuit's substrate, aligned along mutually orthogonal directions.

In some examples, each of the three sensing devices is a resistor (Rx, Ry and Rz where the indices x,y,z denote the dominant proportion of current flow in the respective resistor). When the integrated circuit is subject to mechanical stress, resistors formed in the metal interconnect layers have a small piezo-resistive response. Changes in the macroscopic geometry of the sensing devices formed in the metal interconnect layers (that is, changes in the length, width and thickness of the lines forming the resistor) give rise to a dominant change in resistance. As a result of the relationship between stress in the substrate close to the surface and strain in metal interconnect lines above the substrate surface, it is possible to derive values for the normal in-plane stress components at the integrated circuit's substrate using sensing devices formed in the metal interconnect layers.

The fractional change of a quantity Q can be defined by δQ=(Q−Q0)/Q0 where Q0 is the quantity at zero mechanical stress and Q is the quantity at mechanical stress. Then, the fractional change of the ratio of resistances Rx over Ry, δ(Rx/Ry), is proportional to the difference of in-plane normal stress components, (σₓₓ−σ_{yy}).

Moreover the resistance RL can be defined as the series resistance of Rx and Ry, RL=Rx+Ry, or alternatively, as the parallel resistance of Rx and Ry, RL=1/(1/Rx+1/Ry). Then, the fractional change of the ratio of resistances Rz over RL, δ(Rz/RL), is proportional to the sum of in-plane normal stress components, (σₓₓ+σ_{yy}). In other words, by comparing the electronic property Rz sensed by the vertical sensing device with the electronic property of the first sensing device and the electronic property of the second sensing device, RL, the sum of the in-plane stress components can be obtained.

Therefore, by obtaining an output signal proportional to (δ(Rx/Ry)) and an output signal proportional to (δ(Rz/RL)), it is possible to derive values for σₓₓ and σ_{yy}. This information can then be used to estimate the effect of mechanical stress on the electronic parameters of transistors and other electronic devices forming part of the electronic components of the integrated circuit.

FIG. 7 is a schematic diagram, in plan view, of an integrated circuit 700 comprising a first sensing device 701, wherein the first sensing device 701 is a lateral capacitor. The first sensing device 701 is aligned along the y-direction. The first sensing device 701 comprises a first electrode 702 and a second electrode 703, which are formed in a metal interconnect layer 704 on a semiconductor substrate 706. The first electrode 702 and the second electrode 703 are formed in a comb-shaped manner. Each of the first electrode 702 and the second electrode 703 include a plurality of fingers such that fingers of the first electrode 702 are arranged intermeshing with fingers of the second electrode 703 in order to generate electric fields along the y-direction.

When the integrated circuit 700 is subject to tensile stress in y-direction, σ_{yy}>0, the first electrode 702 and the second electrode 703 of the first sensing device move away from one another. This decreases the capacitance Cy, dCy/dσ_{yy}<0. In another example, the capacitor shown in FIG. 7 may be rotated by 90° in the xy-plane. In this case, the capacitance of the rotated capacitor may be referenced as Cx. The capacitance Cx decreases with tensile stress in x-direction, dCx/dσₓₓ<0. Both, the capacitor shown in FIG. 7 and the capacitor rotated by 90° in the xy plane are lateral capacitors since the electric field between the first electrode 702 and the second electrode 703 is parallel to the x/y plane (parallel to the main surface of the semiconductor substrate 706): In the case of the capacitor shown in FIG. 7, the electric field is pointing in the direction of the y-axis while for the capacitor rotated by 90° the electric field is pointing in the x-direction.

In a similar way as is described in connection with the change in resistance for resistors Rx and Ry, the change in capacitance of the two lateral capacitors, Cx and Cy, can be used to derive the difference in the in-plane normal stress components (σₓₓ−σ_{yy}).

In a further example, a vertical capacitor may be provided. As outlined above, in the vertical capacitor the capacitance Cz is a vertical capacitance. In other words the dominant electric field direction between the first and second electrode of the vertical capacitor is pointing in a direction perpendicular to the substrate (vertical). This is achieved by providing the first electrode in a portion of one metal interconnect layer and providing the second electrode in a portion of another interconnect layer below or above the one metal interconnect layer. The dielectric insulating layer between the two metal interconnect layers provides a dielectric material for the vertical capacitor. In some examples, the first electrode may include a plurality of metal stripes arranged in the one metal interconnect layer extending in a lateral direction and the second electrode may include a plurality of metal stripes arranged in the other metal interconnect layer and extending in a lateral direction with the metal stripes in the one metal interconnect layer overlapping with the metal stripes in the other metal interconnect layer when viewed in the vertical direction. In other examples, the first electrode may include a first metal plate arranged in the one metal interconnect layer and the second electrode may include a second metal plate arranged in the other metal interconnect layer and with the first metal plate overlapping with the metal plate in the other metal interconnect layer when viewed in the vertical direction.

Similarly to the use of lateral and vertical resistors, the lateral capacitors can be combined with a vertical capacitor, Cz, where the electric field between the electrodes points mainly in z-direction, to derive the sum of the in-plane normal stress components (σₓₓ+σ_{yy}). In other words, by comparing the electronic property Cz sensed by the vertical sensing device with the electronic property of the first sensing device and the electronic property of the second sensing device, CL, the sum of the in-plane stress components can be obtained.

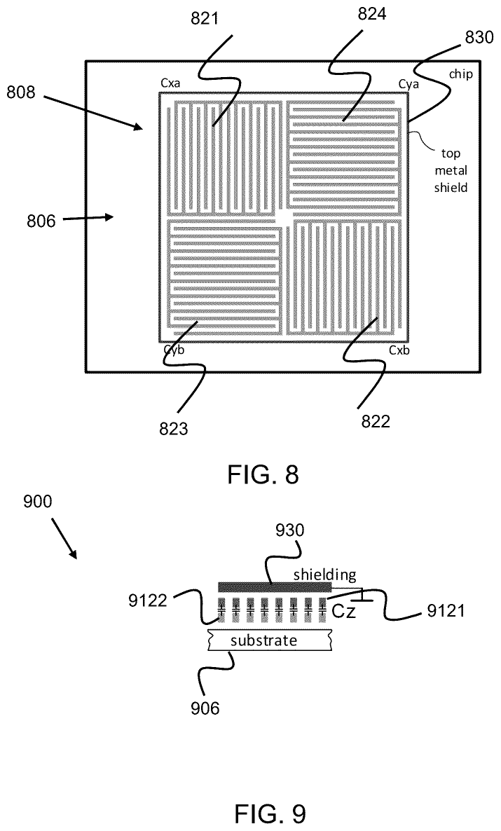

FIG. 8 is a schematic diagram, in plan view, illustrating a sensing arrangement 808 disposed on a substrate 806 comprising four lateral capacitors formed in a metal interconnect layer. The first sensing device comprises a first lateral capacitor 821 and a second lateral capacitor 822, each of which is aligned along a first direction. The second sensing device comprises a third lateral capacitor 823 and a fourth lateral capacitor 824, each of which is aligned along a second direction substantially orthogonal to the first direction.

A shielding layer 830, adapted to prevent/mitigate the effects of electromagnetic interference, is disposed on the sensing arrangement.

FIG. 9 illustrates a cross sectional partial view of an example of an integrated circuit 900, in which a shielding layer 930 is provided in combination with a capacitor. The capacitor is formed from the first metal interconnect layer 9121 and a second metal interconnect layer 9122. The capacitor is aligned in a direction substantially orthogonal to the upper surface of the substrate 906.

As discussed above, integrated circuits having sensing arrangements including multiple sensing devices adapted to respond different to mechanical stress applied to the integrated circuit may comprise an evaluation circuit configured to compare the responses of the sensing devices. In general, many ways exist to measure a resistance or a capacitance and may be used to evaluate the responses of the sensing device. Techniques may include for example bridge configurations and application of DC and/or AC signals. Various examples of suitable evaluation circuits will now be described.

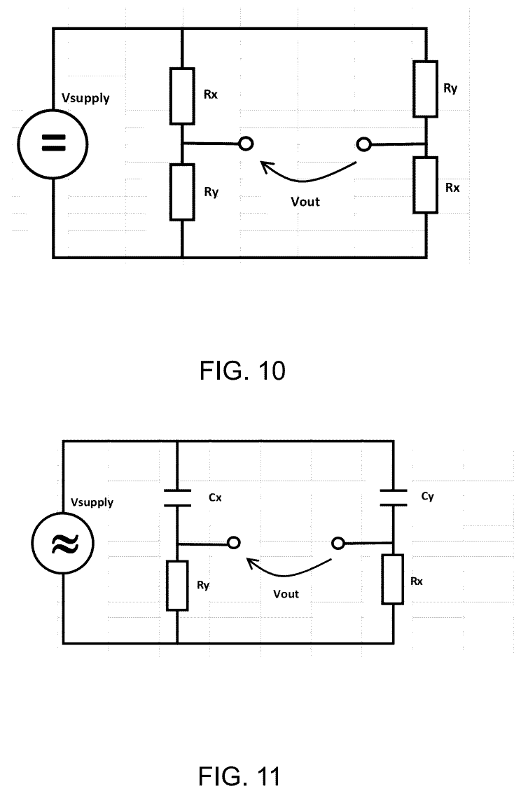

FIG. 10 is a schematic diagram of an example of a sensing arrangement having resistors Rx, Ry and an evaluation circuit (a Wheatstone bridge circuit) adapted to generate an output signal proportional to (δ(Rx/Ry)).

In this example, the sensing arrangement comprises four resistors formed within the plurality of metal interconnect layers. Two resistors (Rx) are aligned along the x-direction, and two resistors (Ry) are aligned along the y-direction. A first one of the Rx resistors and a first one of the Ry resistors are connected in series in a first leg of the Wheatstone bridge circuit with the first one of the Rx resistors connected to a first potential (e.g., supply voltage Vsupply) and the first one of the Ry resistors connected to a second potential (e.g., ground). A second one of the Ry resistors and a second one of the Rx resistors are connected in series in a second leg of the Wheatstone bridge circuit with the second one of the Ry resistors connected to the first potential and the second one of the Rx resistors connected to the second potential.

As the resistors aligned along the x-direction and the resistors aligned along the y-direction are formed of the same material and have similar/the same shape, they have similar/the same temperature coefficient. Therefore, even if the circuit exhibits an offset error as a result of the resistances Rx and Ry being slightly different, that offset error is straightforward to account for. Note that it is assumed the supply voltage, V_{supply}, is not temperature-dependent, so any offset error would also be constant with temperature.

The stress sensitivity of the output signal, Vₒᵤₜ, has a very low temperature drift and does not vary with doping used in silicon substrates. Therefore, the integrated circuit has good reproducibility within typical manufacturing tolerances.

Assuming that the output signal Vₒᵤₜ, is the voltage between a first node located between the resistors of the first branch of the bridge and a second node located between the two resistors of the second branch of the bridge, the ratio of Vₒᵤₜ/V_{supply} can be written as Vₒᵤₜ/V_{supply}=(Rx−Ry)/(Rx+Ry). This can be approximated to Vₒᵤₜ/V_{supply}≅δ(Rx/Ry)/2.

If Rx is replaced in FIG. 10 with RL and Ry in FIG. 10 with Rz, the output voltage is proportional to (δ(Rz/RL)). The first output signal proportional to (δ(Rx/Ry)) and the second output signal proportional to (6 (Rz/RL)) can be used to derive individual values for the in-plane normal mechanical stress components (σₓₓ, σ_{yy}).

Rz is partly formed by vias. Therefore, Rz may have a different temperature coefficient to RL, leading to a temperature-dependent offset error. The temperature dependence will, however, be stable over production lots and is not complex to account for. The stress-sensitivity of the output signal also has a very low temperature drift, and a similar manufacturing tolerance as the stress-sensitivity of the Rx/Ry-bridge.

The above-described evaluation circuit can be used for a sensing arrangement which comprises capacitors instead of resistors (the replacement capacitor being aligned in the same direction as the resistor it replaces).

FIG. 11 illustrates an example sensing arrangement and evaluation circuit for deriving the difference (σₓₓ−σ_{yy}) between the two in-plane normal mechanical stress components. In this example, the sensing arrangement comprises two resistors Rx, Ry and two capacitances Cx and Cy formed within the plurality of metal interconnect layers. Capacitance Cx and Resistor Ry are connected in series in a first leg of a Wheatstone bridge circuit with the capacitance Cx connected to a first potential (e.g., Vsupply) and the resistor Ry connected to a second potential (e.g., ground). Capacitance Cy and resistor Rx are connected in series in a second leg of the Wheatstone bridge circuit with the capacitance Cy connected to the first potential and the resistor Rx connected to the second potential. An AC signal V_{supply} is applied to the Wheatstone Bridge. Defining complex impedances, the ratio of Vₒᵤₜ to V_{supply} can be obtained to be to be Vₒᵤₜ/V_{supply}=Rx/(Rx+1/(jωCy))−Ry/(Ry+1/(jωCx)). This can be approximated to Vₒᵤₜ/V_{supply}=1/(1+ω₁/jω)−1/(1+ω₂/jω)=C(σₓₓ−σ_{yy})jω/ω₀/(ω/ω₀−j)² for small and moderate stress with ω₁=1/Rx/Cy, ω₂=1/Ry/Cx and ω₀=ω₁=ω₂ at zero stress and C a constant of proportionality. The ratio of Vₒᵤₜ to V_{supply} is proportional to the difference between the in-plane normal stress components (σₓₓ−σ_{yy}). The constant of proportionality depends on the Young's modulus and the Poisson ratio of the substrate. For a silicon substrate and at resonance frequency ω=ω₀:

$$\frac{{V}_{out}}{{V}_{supply}} = 1.1 \% / GPa ( {σ}_{xx} - {σ}_{yy} )$$

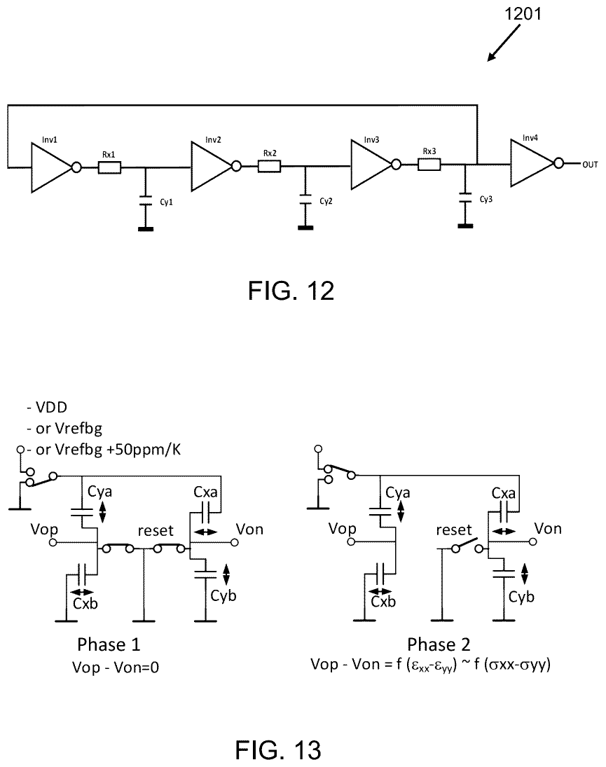

FIG. 12 shows a circuit diagram of a sensing device comprising an oscillator for use with an example sensing arrangement. The sensing arrangement comprises a first sensing device 1201, a second sensing device and a third sensing device. Each of the sensing devices comprises an oscillator. The oscillator comprises an odd number of inverters in a feedback loop, each of which is loaded by an RC member. The frequency of the oscillator varies with the RC time constants of the RC members.

In the first sensing device 1201, each of the resistors is aligned along a first direction, and each of the lateral capacitors is aligned along a second direction substantially orthogonal to the first direction. The first oscillator outputs a signal having a frequency that decreases in response to increased tension along the first direction. The frequency of the first oscillator comprises a component proportional to the difference (σₓₓ−σ_{yy}) between the two in-plane normal mechanical stress components.

In the second sensing device, a further oscillator can be provided, in which each resistor aligned along the first direction in FIG. 12 is replaced by a resistor aligned along the second direction, and each capacitor aligned along the second direction in FIG. 12 is replaced by a capacitor aligned along the first direction. The output frequency of the second oscillator increases with tension along the first direction. An evaluation circuit adapted to compare the frequency of the first oscillator and the frequency of the second oscillator (e.g., by counting the pulses at OUT in a reasonably long time interval) is provided, to determine (σₓₓ−σ_{yy}).

To derive information about the individual values for the in-plane normal mechanical stress components, a third oscillator is provided. In the third oscillator, each resistor aligned along the first direction in FIG. 12 is replaced by: (i) the combination of a resistor aligned in the first direction connected in series or parallel with a resistor aligned in the second direction, or (ii) a resistor aligned along a third direction substantially orthogonal to both the first and second directions. Further, the capacitor aligned in the second direction is replaced by either: (i) a capacitor aligned in the third direction or a capacitor aligned in the second direction connected in parallel to capacitor aligned in the first direction. The output frequency of the third oscillator is proportional to the sum of the in-plane normal mechanical stress components (σₓₓ+σ_{yy}). It is to be understood that the oscillator shown in FIG. 12 is only one of many examples of a suitable oscillator. Accordingly, in other examples different implementations and different types of oscillators can be used.

FIG. 13 shows an evaluation circuit adapted to output a signal having a property proportional to the difference between the in-plane normal mechanical stress components (σₓₓ−σ_{yy}) for the sensing arrangement of FIG. 8. The evaluation circuit is a switched circuit that operates as a DC bridge circuit. In the left hand side configuration, the two legs of the bridge are balanced, so the difference between the supply voltage and the output voltage is approximately zero. In the right hand side configuration, the difference between the supply voltage and the output voltage is proportional to the difference between the in-plane normal mechanical stress components (σₓₓ−σ_{yy}).

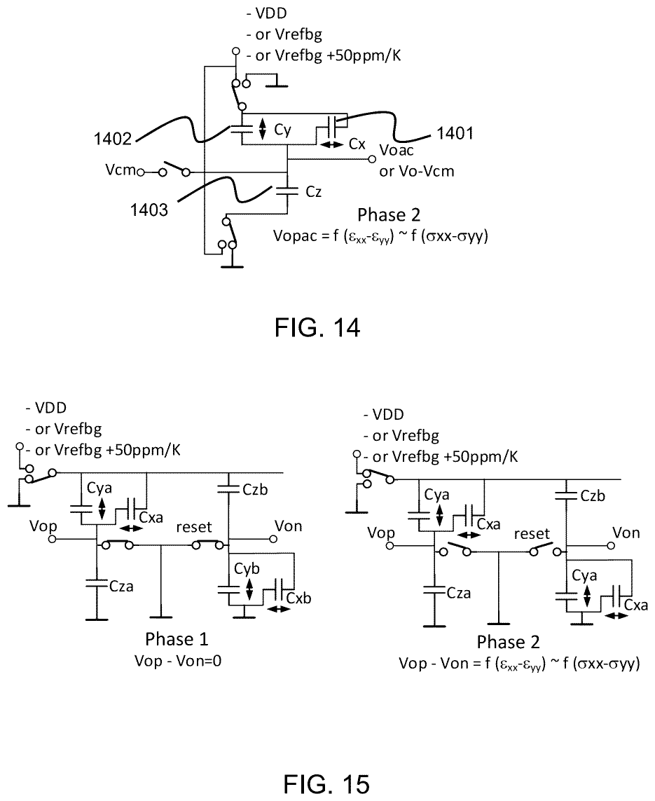

FIG. 14 shows an example of a sensing arrangement comprising three sensing devices and an evaluation circuit adapted to output a signal having a property proportional to the difference between the in-plane normal mechanical stress components (σₓₓ−σ_{yy}). The first sensing device 1401 comprises a lateral capacitor aligned along the x-direction. The second sensing device 1402 comprises a lateral capacitor aligned along the y-direction. The third sensing device 1403 comprises a capacitor aligned along the z-direction. The evaluation circuit is adapted to output a signal having a property proportional to the difference between the in-plane normal mechanical stress components (σₓₓ−σ_{yy}).

FIG. 15 shows an example of an evaluation circuit adapted to output a signal having a property proportional to the difference between the in-plane normal mechanical stress components (σₓₓ−σ_{yy}) and to output a signal having a property proportional to the sum of the in-plane normal mechanical stress components (σₓₓ+σ_{yy}).

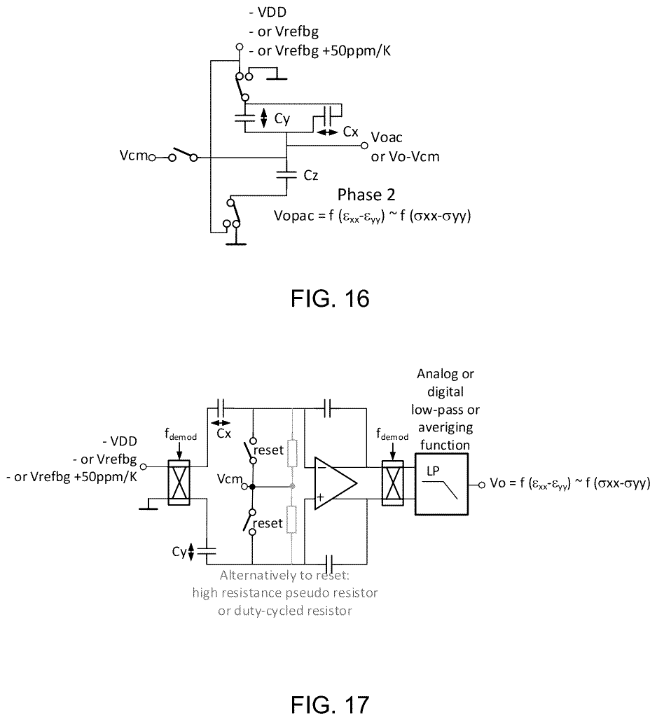

FIG. 16 shows an example of an evaluation circuit adapted to output a signal having a property proportional to the difference between the in-plane normal mechanical stress components (σₓₓ−σ_{yy}) and to output a signal having a property proportional to the sum of the in-plane normal mechanical stress components (σₓₓ+σ_{yy}). The sensing arrangement comprises a capacitor aligned along the x-direction, a capacitor aligned along the y-direction and a capacitor aligned along the z-direction.

FIG. 17 is a diagram illustrating an evaluation circuit for deriving the difference (σₓₓ−σ_{yy}) of the in-plane normal mechanical stress components using capacitors. The sensing arrangement comprises a capacitor aligned along the x-direction and a capacitor aligned along the y-direction.

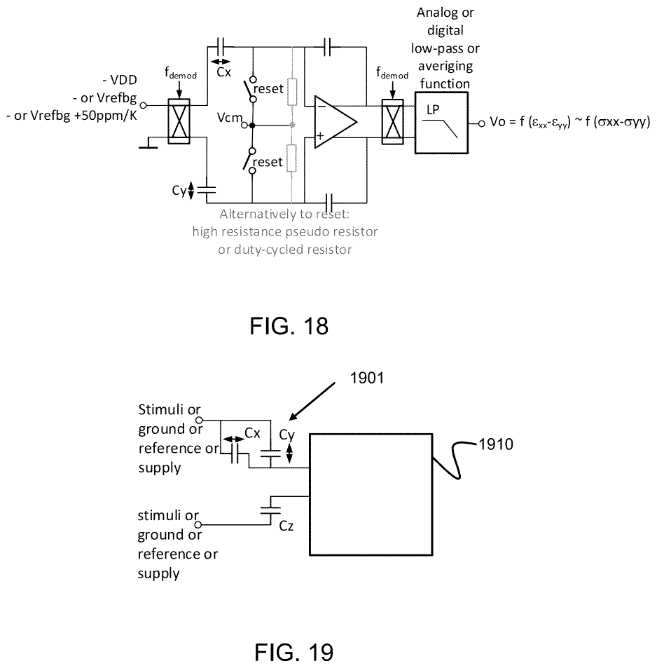

FIG. 18 is a diagram illustrating a general structure for an evaluation circuit for deriving the difference (σₓₓ−σ_{yy}) of the in-plane normal mechanical stress components using capacitors. The sensing arrangement comprises a capacitor aligned along the x-direction and a capacitor aligned along the y-direction.

FIG. 19 is a diagram illustrating a general structure for an evaluation circuit for deriving the difference (σₓₓ−σ_{yy}) of the in-plane normal mechanical stress components using capacitors, for a sensing arrangement comprising three capacitors aligned in respective orthogonal directions. The sensing arrangement comprises a first capacitor aligned along the x-direction, a second capacitor aligned along the y-direction. These capacitors are coupled to a first stimuli/ground/reference/supply. A third capacitor is aligned along the z-direction and coupled to a second stimuli/ground/reference/supply. The sensing arrangement is coupled to circuit 1910. Circuit 1910 may be a switched capacitor or continuous time capacitive evaluation circuit, such as: an amplifier, an analogue to digital converter, a comparator, and integrator, a differential transistor input stage, a gm-C circuit, a frequency measurement circuit or a delay or phase measurement circuit. The circuit 1910 is adapted to output a first signal having a property proportional to the difference or ratio between the capacitance of the first capacitor and the second capacitor, and a second signal having a property proportional to the difference or ratio between the capacitance of the third capacitor and a combination of the capacitances of the first capacitor and the second capacitor.

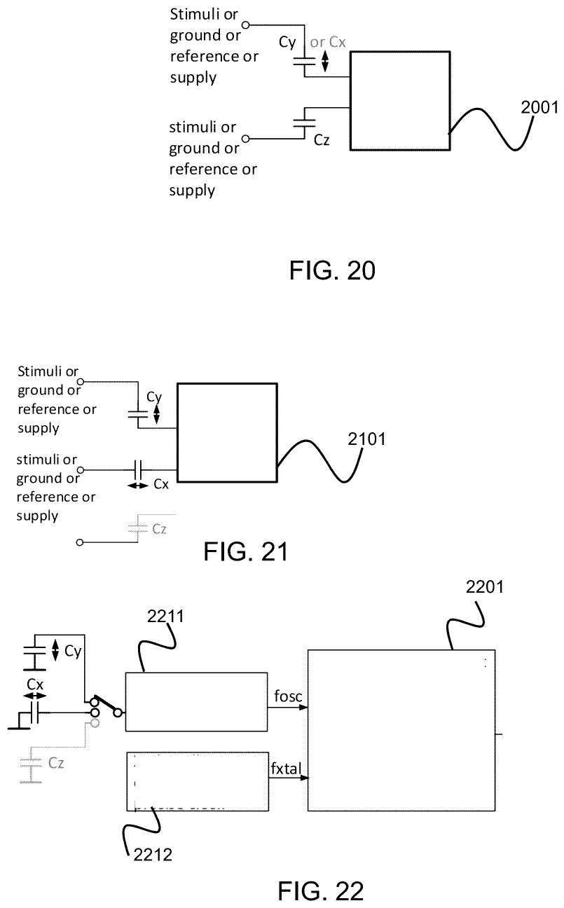

FIG. 20 is a diagram illustrating a sensing arrangement and a general structure for an evaluation circuit. The sensing arrangement comprises two capacitors aligned in respective orthogonal directions. The sensing arrangement comprises a capacitor aligned along the z-direction and a capacitor aligned along the y-direction, each coupled to respective stimuli/ground/reference/supply. The sensing arrangement is coupled to evaluation circuit 2001. Evaluation circuit 2001 may be a switched capacitor or continuous time capacitive evaluation circuit, such as: an amplifier, an analogue to digital converter, a comparator, and integrator, a differential transistor input stage, a gm-C circuit, a frequency measurement circuit or a delay or phase measurement circuit. The evaluation circuit 2001 is adapted to output a signal having a property proportional to the sum of the normal in-plane mechanical stress components.

The same circuit could be used with a capacitor aligned in the x-direction, rather than the y-direction.

FIG. 21 is a diagram illustrating a general structure for a sensing arrangement and an evaluation circuit. The sensing arrangement comprises a first capacitor aligned along the x-direction, a second capacitor aligned along the y-direction and a third capacitor aligned along the z-direction. The circuit 2101 is adapted to derive a difference between the capacitance of the first capacitor and the second capacitor, or a ratio of the capacitance of the first capacitor to the second capacitor. The circuit 2101 may comprise an amplifier, an analogue to digital converter, a comparator, and integrator, a differential transistor input stage, a gm-C circuit, a frequency measurement circuit and/or a delay or phase measurement circuit. The circuit may be further adapted to derive a difference between the capacitance of the third capacitor and a combination of the first capacitor and the second capacitor, or a ratio of the capacitance of the third capacitor to the combination of the capacitances of the first and second capacitors.

FIG. 22 is a diagram illustrating a general structure for a digital evaluation circuit for deriving in-plane normal stress components using capacitors. The sensing arrangement comprises a first capacitor aligned along the y-direction and a second capacitor aligned along the x-direction. The sensing arrangement is coupled to an evaluation circuit 2201 adapted to output a signal having a property with a component proportional to the difference of ratio of the capacitances of the first and second capacitors. The evaluation circuit is coupled to an oscillator circuit 2211 (coupled to the sensing arrangement) and an external clock. The outputs of the oscillator 2211 and the clock 2212 are input into the evaluation circuit 2201. The evaluation circuit is adapted to determine the difference or the ratio between the capacitances of the first and second capacitors. Alternatively, the evaluation circuit may perform an absolute frequency of a delay measurement.

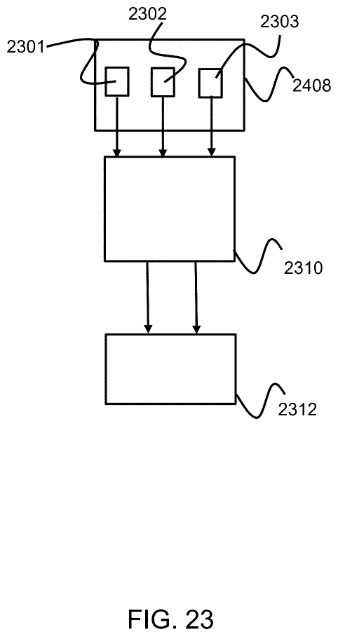

FIG. 23 is a schematic diagram illustrating the operation of an integrated circuit 2300 comprising a stress compensation circuit. The integrated circuit 2300 comprises a sensing arrangement 2308 including a first sensing device 2301, a second sensing device 2302 and a third sensing device 2303. Each of the sensing devices is formed in the plurality of metal interconnect layers disposed on the substrate of the integrated circuit.

The integrated circuit 2300 further comprises an evaluation circuit 2310 adapted to compare the electronic property of the first sensing device with the electronic property of the second sensing device and to output a first signal. That is, the evaluation circuit 2310 outputs a first signal having a property that varies with the difference between the first electronic property and the second electronic property, of the ratio of the first electronic property to the second electronic property. The evaluation circuit is further adapted to compare the electronic property of the third sensing device with the combination of the electronic properties of the first and second sensing device, and to output a second signal having a property that varies with the difference or ratio.

The evaluation circuit 2300 further comprises a stress compensation circuit 2312 adapted to derive the in-plane normal stress components based on the first signal and the second signal.

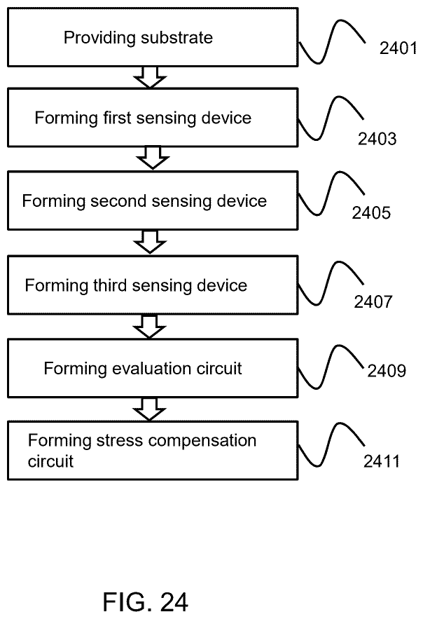

FIG. 24 illustrates a method of manufacturing an integrated circuit. The method comprises providing, 2401, a semiconductor substrate and forming a plurality of metal interconnect layers, including a first metal interconnect layer, on the substrate.

Forming the metal interconnect layers, 2403, comprises forming a sensing arrangement adapted to provide an output signal comprising a component proportional to a change in mechanical stress applied to the integrated circuit. In particular, the sensing arrangement comprises forming a first sensing device in the first metal interconnect layer wherein the first sensing device is arranged to produce a change in an electronic property of the first sensing device in response to a change in mechanical stress applied to the integrated circuit.

Forming a plurality of vias connecting the metal interconnect layers and wherein the third sensing device is formed in the plurality of metal interconnect layers and the plurality of vias.

A second sensing device is formed, 2405, in the plurality of metal interconnect layers. The second sensing device is arranged to produce a change in an electronic property of the second sensing device in response to a change in mechanical stress applied to the integrated circuit.

Further, a third sensing device is formed, 2407, in the plurality of metal interconnect layers. The sensing device is arranged to produce a change in an electronic property of the first sensing device in response to a change in mechanical stress applied to the integrated circuit.

Each of the first sensing device, the second sensing device and the third sensing device comprises a capacitor, a resistor or a resistor-capacitor circuit.

An evaluation circuit is integrated, 2409, on the semiconductor substrate. The evaluation circuit is adapted to compare the responses of the first sensing device and the second sensing device.

The method further comprises integrating, 2411, a stress compensation circuit. At least one of the following circuits: a bandgap voltage reference circuit, an oscillator circuit and a Hall effect sensor circuit may be integrated on the substrate. The stress compensation circuit is configured to reduce the mechanical stress dependency for the at least one circuit.

### Aspects

In addition to the above-described examples, the following aspects are disclosed.

Aspect 1 is an integrated circuit comprising:
a. a semiconductor substrate comprising a plurality of electronic components;
b. a plurality of metal interconnect layers stacked on the semiconductor substrate, wherein the plurality of metal interconnect layers electrically connect the electronic components together; and
c. a sensing arrangement adapted to provide an output signal comprising a component proportional to mechanical stress applied to the integrated circuit, wherein the sensing arrangement is formed in the plurality of metal interconnect layers, the sensing arrangement comprising:
d. a first sensing device at least partly formed by a metal interconnect layer of the plurality of metal interconnect layers, wherein the first sensing device is arranged to produce a change in an electronic property of the first sensing device in response to a change in mechanical stress applied to the integrated circuit.

Aspect 2 is the integrated circuit of aspect 1 wherein the integrated circuit comprises a plurality of vias connected to the plurality of metal interconnect layers, wherein the first sensing device is formed by at least one via of the plurality of vias and at least two metal interconnect layers of the plurality of metal interconnect layers.

Aspect 3 is the integrated circuit of aspect 1 wherein:
a. the sensing arrangement further comprises a second sensing device, wherein the second sensing device is arranged to produce a change in an electronic property of the second sensing device in response to a change in stress applied to the integrated circuit, and
b. each of the first sensing device and the second sensing device comprises:
i. a capacitor, wherein the electronic property is capacitance; or
ii. a resistor, wherein the electronic property is resistance; or
iii. a resistor-capacitor circuit, wherein the electronic property is the RC time constant of the resistor-capacitor circuit.

Aspect 4 is the integrated circuit of aspect 3 wherein the first sensing device and the second sensing device are arranged such that the electronic property of the first sensing device and the electronic property of the second sensing device respond differently to the change in mechanical stress applied to the integrated circuit, and the semiconductor substrate further comprises an integrated evaluation circuit configured to compare the electronic property of the first sensing device with the electronic property of the second sensing device.

Aspect 5 is the integrated circuit of aspect 4, wherein the integrated evaluation circuit is configured to output a first signal, wherein a property of the first signal varies with:
1. the ratio of the electronic property of the first sensing device and the electronic property of the second sensing device; or
2. the difference between the electronic property of the first sensing device and the electronic property of the second sensing device, wherein the electronic property of the first sensing device and the electronic property of the second sensing device refer to the same electronic property of the respective sensing device.

Aspect 6 is the integrated circuit of any one of aspect 3 to aspect 5, wherein the first sensing device is aligned along a first direction parallel to the plane of the surface of the semiconductor substrate and the second sensing device is aligned along a second direction parallel to the plane of the surface of the semiconductor substrate, wherein the first direction and the second direction are substantially orthogonal to one another.

Aspect 7 is the integrated circuit of aspect 6 wherein:
a. the sensing arrangement further comprises a third sensing device arranged to produce a change in an electronic property of the third sensing device in response to a change in mechanical stress applied to the integrated circuit, wherein the third sensing device is aligned along a third direction substantially orthogonal to the first direction and the second direction; and
b. the integrated evaluation circuit is further configured to compare the electronic property of the third sensing device with the electronic property of the first sensing device and the electronic property of the second sensing device.

Aspect 8 is the integrated circuit of aspect 7 further comprising a plurality of vias connected to the plurality of metal interconnect layers, wherein the third sensing device comprises at least one via of the plurality of vias and at least two metal interconnect layers of the plurality of metal interconnect layers.

Aspect 9 is the integrated circuit of aspect 7 or aspect 8 wherein:
a. the first sensing device, the second sensing device and the third sensing device each comprise a resistor configured to produce a change in resistance in response to a change in mechanical stress applied to the integrated circuit;
b. the first sensing device is arranged to conduct a current predominantly along the first direction;
c. the second sensing device is arranged to conduct a current predominantly along the second direction, wherein the first sensing device and the second sensing device are orientated substantially orthogonally to one another;
d. the third sensing device is arranged to conduct a current predominantly along the third direction.

Aspect 10 is the integrated circuit of aspect 9 wherein:
a. the first signal varies with the change in a ratio (R₁/R₂) of the resistance, R₁, of the first sensing device to the resistance, R₂, of the second sensing device; and
b. the integrated evaluation circuit is configured to output a second signal that varies with a change in the ratio (R₃/R_{L}) of the resistance, R₃, of the third sensing device to a combination, R_{L}, of the resistance of the first sensing device and the resistance of the second sensing device.

Aspect 11 is the integrated circuit of aspect 9 or aspect 10 wherein each of the resistors comprises a conductive path in the form of a meander pattern.

Aspect 12 is the integrated circuit of aspect 6 or aspect 7 wherein:
a. the first sensing device and the second sensing device are each lateral capacitors configured to produce a change in capacitance in response to a change in mechanical stress applied to the integrated circuit;
b. each of the first sensing device and the second sensing device comprises a first electrode and a second electrode, wherein the electrodes of each respective sensing device are separated laterally in a direction parallel to the plane of the surface of the semiconductor substrate, wherein the first sensing device and the second sensing device are orientated essentially orthogonally to one another; and
c. the third sensing device is a capacitor aligned substantially orthogonally to the surface of the semiconductor substrate.

Aspect 13 is the integrated circuit of aspect 12 wherein the first signal varies with the change in the ratio (C₁/C₂) of the capacitance, C₁, of the first sensing device to the capacitance, C₂, of the second sensing device and the integrated evaluation circuit is configured to output a second signal that varies with the ratio, C₃/C_{L}, of the capacitance, C₃, of the third sensing device to a combination, C_{L}, of the capacitance, C₁, of the first sensing device and the capacitance, C₂, of the second sensing device.

Aspect 14 is the integrated circuit of aspect 7 wherein:
a. the first sensing device comprises a first resistor-capacitor circuit comprising a first resistor and a first capacitor;
b. the second sensing device comprises a second resistor-capacitor circuit comprising a second resistor and a second capacitor;
c. the first resistor is arranged to conduct a current predominantly along a third direction parallel to the plane of the surface of the semiconductor substrate;
d. the second resistor is arranged to conduct a current predominantly along a fourth direction substantially orthogonal to the fourth direction; and
e. the evaluation circuit is configured to compare the RC time constant of the first sensing device with the RC time constant of the second sensing device.

Aspect 15 is the integrated circuit of aspect 7 wherein the integrated circuit comprises:
a. a first oscillator configured to output a first oscillator signal having a frequency that varies as a function of the RC time constant of the first sensing device;
b. a second oscillator configured to output a second oscillator signal having a frequency that varies as a function of the RC time constant of the second sensing device; and
c. the evaluation circuit is configured to compare the frequency of the first oscillator signal and the frequency of the second oscillator signal.

Aspect 16 is the integrated circuit of aspect 15 further comprising a third oscillator configured to output a third oscillator signal having a frequency that varies as a function of the RC time constant of the third sensing device.

Aspect 17 is the integrated circuit of any one of aspects 7 to 13 and 16 further comprising a stress compensation circuit and the plurality of electronic components comprise at least one of the following circuits: a bandgap voltage reference circuit, an oscillator circuit or a Hall effect sensor circuit, wherein the stress compensation circuit is configured to reduce the mechanical stress dependency for the at least one circuit based on at least one output of the evaluation circuit.

Aspect 18 is the integrated circuit of any one of aspects 7 to 17 further comprising a stress compensation circuit configured to derive a correction factor for correcting a parameter of at least one of the electronic components based on at least one output of the evaluation circuit.

Aspect 19 is the integrated circuit of aspect 18 wherein the stress compensation circuit is further configured to apply the correction factor to a circuit of at least one of the electronic components to reduce the effect of mechanical stress on the circuit of the electronic component.

Aspect 20 is the integrated circuit of any one of aspects 7 to 19 wherein the evaluation circuit is configured to:
a. derive a first evaluation signal proportional to the difference between a first normal mechanical stress component acting on the integrated circuit and a second normal stress component acting on the integrated circuit; and
b. derive a second evaluation signal proportional to the sum of the first normal stress component and the second normal stress component.

Aspect 21 is the integrated circuit of any one of aspects 1 to 20, wherein the thickness of each of the metal interconnect layers of the plurality of metal interconnect layers is less than 1 micrometer.

Aspect 22 is the integrated circuit of any one of aspects 1 to 21 wherein the plurality of electronic components comprises a plurality of Fin field effect transistors (FinFETs) having process nodes equal to or less than 28 nm.

Aspect 23 is a method of manufacturing an integrated circuit, the method comprising:
a. providing a semiconductor substrate; and
b. forming a plurality of metal interconnect layers on the substrate including a first metal interconnect layer, wherein:
c. forming the metal interconnect layers comprises forming a sensing arrangement adapted to provide an output signal comprising a component proportional to a change in mechanical stress applied to the integrated circuit; and
d. forming the sensing arrangement comprises forming a first sensing device in the first metal interconnect layer wherein the first sensing device is arranged to produce a change in an electronic property of the first sensing device in response to a change in mechanical stress applied to the integrated circuit.

Aspect 24 is the method of aspect 23 further comprising:
forming a second sensing device in the plurality of metal interconnect layers wherein the second sensing device is arranged to produce a change in an electronic property of the second sensing device in response to a change in mechanical stress applied to the integrated circuit; and
integrating an evaluation circuit configured to determine a first signal, wherein the first signal varies with:
1. the difference between the electronic property of the first sensing device and the electronic property of the second sensing device, or
2. the ratio of the electronic property of the first sensing device and the electronic property of the second sensing device.

Aspect 25 is the method of aspect 24 wherein each of the first sensing device and the second sensing device comprises:
a. a capacitor, wherein the electronic property is capacitance; or
b. a resistor, wherein the electronic property is resistance; or
c. a resistor-capacitor circuit, wherein the electronic property comprises RC time constant of the resistor-capacitor circuit.

Aspect 26 is the method of aspect 24 or aspect 25 further comprising forming a third sensing device arranged to produce a change in an electronic property of the first sensing device in response to a change in mechanical stress applied to the integrated circuit.

Aspect 27 is the method of aspect 26 further comprising forming a plurality of vias connecting the metal interconnect layers and wherein the third sensing device is formed in the plurality of metal interconnect layers and the plurality of vias.

Aspect 28 is the method of aspect 26 or aspect 27 further comprising:
a. integrating a stress compensation circuit; and
b. integrating at least one of the following circuits: a bandgap voltage reference circuit, an oscillator circuit and a Hall effect sensor circuit, wherein the stress compensation circuit is configured to reduce the mechanical stress dependency for the at least one circuit.

Aspect 29 is the method of aspect 28 wherein the stress compensation circuit is configured to derive a correction factor for correcting a parameter of at least one of the electronic components based on the first signal and the second signal.

Aspect 30 is the method of any one of aspects 23 to 29 wherein the plurality of electronic components comprises a plurality of Fin field effect transistors (FinFETs) having process nodes equal to or less than 28 nm.

Although specific aspects have been illustrated and described herein, it will be appreciated by those of ordinary skill in the art that a variety of alternate and/or equivalent implementations may be substituted for the specific aspects shown and described without departing from the scope of the present implementation. This application is intended to cover any adaptations or variations of the specific aspects discussed herein. Therefore, it is intended that this implementation be limited only by the claims and the equivalents thereof.

For example, although the integrated circuit of FIG. 1 comprises four metal interconnect layers it will be understood that the integrated circuit may comprise fewer or more metal interconnect layers.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

1. An integrated circuit comprising:
a semiconductor substrate comprising a plurality of electronic components;
a plurality of metal interconnect layers stacked on the semiconductor substrate, wherein the plurality of metal interconnect layers electrically connect the electronic components together; and
a sensing arrangement adapted to provide an output signal comprising a component proportional to mechanical stress applied to the integrated circuit, wherein the sensing arrangement is formed in the plurality of metal interconnect layers,
wherein the sensing arrangement comprises:
a first sensing device at least partly formed by a metal interconnect layer of the plurality of metal interconnect layers, wherein the first sensing device is arranged to produce a change in an electronic property of the first sensing device in response to a change in mechanical stress applied to the integrated circuit.

2. The integrated circuit of claim 1, wherein the integrated circuit comprises a plurality of vias connected to the plurality of metal interconnect layers, and
wherein the first sensing device is formed by at least one via of the plurality of vias and at least two metal interconnect layers of the plurality of metal interconnect layers.

3. The integrated circuit of claim 1 wherein:
the sensing arrangement further comprises a second sensing device, wherein the second sensing device is arranged to produce a change in an electronic property of the second sensing device in response to a change in stress applied to the integrated circuit, and
each of the first sensing device and the second sensing device comprises:
a capacitor, wherein the electronic property is capacitance; or
a resistor, wherein the electronic property is resistance; or
a resistor-capacitor circuit, wherein the electronic property is an RC time constant of the resistor-capacitor circuit.

4. The integrated circuit of claim 3, wherein the first sensing device and the second sensing device are arranged such that the electronic property of the first sensing device and the electronic property of the second sensing device respond differently to the change in mechanical stress applied to the integrated circuit, and the semiconductor substrate further comprises an integrated evaluation circuit configured to compare the electronic property of the first sensing device with the electronic property of the second sensing device.

5. The integrated circuit of claim 4, wherein the integrated evaluation circuit is configured to output a first signal, wherein a property of the first signal varies with:
(i) a ratio of the electronic property of the first sensing device and the electronic property of the second sensing device; or
(ii) a difference between the electronic property of the first sensing device and the electronic property of the second sensing device, wherein the electronic property of the first sensing device and the electronic property of the second sensing device refer to the same electronic property of the respective sensing device.

6. The integrated circuit of claim 3, wherein the first sensing device is aligned along a first direction parallel to a plane of a surface of the semiconductor substrate and the second sensing device is aligned along a second direction parallel to the plane of the surface of the semiconductor substrate, and
wherein the first direction and the second direction are substantially orthogonal to one another.

7. The integrated circuit of claim 4, wherein:
the sensing arrangement further comprises a third sensing device arranged to produce a change in an electronic property of the third sensing device in response to a change in mechanical stress applied to the integrated circuit, wherein the third sensing device is aligned along a third direction substantially orthogonal to the first direction and the second direction; and
the integrated evaluation circuit is further configured to compare the electronic property of the third sensing device with the electronic property of the first sensing device and the electronic property of the second sensing device.

8. The integrated circuit of claim 7, further comprising:
a plurality of vias connected to the plurality of metal interconnect layers,
wherein the third sensing device comprises at least one via of the plurality of vias and at least two metal interconnect layers of the plurality of metal interconnect layers.

9. The integrated circuit of claim 7 wherein:
the first sensing device, the second sensing device, and the third sensing device each comprise a resistor configured to produce a change in resistance in response to a change in mechanical stress applied to the integrated circuit;
the resistor of the first sensing device is arranged to conduct in at least one of the plurality of metal interconnect layers a current predominantly along the first direction;
the resistor of the second sensing device is arranged to conduct in at least one of the plurality of metal interconnect layers a current predominantly along the second direction, wherein the first sensing device and the second sensing device are orientated substantially orthogonally to one another; and
the resistor of the third sensing device is arranged to conduct between at least two of the plurality of metal interconnect layers a current predominantly along the third direction.

10. The integrated circuit of claim 9 wherein:
the first signal varies with a mechanical stress dependent change in a ratio of a resistance of the first sensing device to a resistance of the second sensing device, and
the integrated evaluation circuit is configured to output a second signal that varies with a mechanical stress dependent change in a ratio of a resistance of the third sensing device to a combination of the resistance of the first sensing device and the resistance of the second sensing device.

11. The integrated circuit of claim 9, wherein each of the resistors comprises a conductive path in the form of a meander pattern.

12. The integrated circuit of claim 7, wherein:
the first sensing device and the second sensing device are each lateral capacitors configured to produce a change in capacitance in response to a change in mechanical stress applied to the integrated circuit;
each of the first sensing device and the second sensing device comprises a first electrode and a second electrode formed in at least one of the plurality of metal interconnect layers, wherein the electrodes of each respective sensing device are separated laterally in a direction parallel to a plane of a surface of the semiconductor substrate, wherein the first sensing device and the second sensing device are orientated essentially orthogonally to one another; and
the third sensing device is a vertical capacitor aligned substantially orthogonally to the surface of the semiconductor substrate, wherein the vertical capacitor comprises a first electrode formed in at least a first metal interconnect layer of the plurality of metal interconnect layers and a second electrode formed in at least a second metal interconnect layer of the plurality of metal interconnect layers.

13. The integrated circuit of claim 12, wherein:
the first signal varies with the change in a ratio of a capacitance of the first sensing device to a capacitance of the second sensing device, and
the integrated evaluation circuit is configured to output a second signal that varies with a ratio of a capacitance of the third sensing device to a combination of the capacitance of the first sensing device and the capacitance of the second sensing device.

14. The integrated circuit of claim 7, wherein:
the first sensing device comprises a first resistor-capacitor circuit comprising a first resistor and a first capacitor;
the second sensing device comprises a second resistor-capacitor circuit comprising a second resistor and a second capacitor;
the first resistor is arranged to conduct in at least one of the plurality of metal interconnect layers a current predominantly along a third direction parallel to a plane of a surface of the semiconductor substrate;
the second resistor is arranged to conduct in at least one of the plurality of metal interconnect layers a current predominantly along a fourth direction substantially orthogonal to the fourth direction;
the first capacitor comprises electrodes formed in at least one of the plurality of metal interconnect layers to provide an electric field predominantly along the third direction;
the second capacitor comprises electrodes formed in at least one of the plurality of metal interconnect layers to provide an electric field predominantly along the second direction; and
the evaluation circuit is configured to compare the RC time constant of the first sensing device with the RC time constant of the second sensing device.

15. The integrated circuit of claim 7, wherein:
the first sensing device comprises a first resistor-capacitor circuit comprising a first resistor and a first capacitor;
the second sensing device comprises a second resistor-capacitor circuit comprising a second resistor and a second capacitor;
wherein the integrated circuit further comprises:
a first oscillator configured to output a first oscillator signal having a frequency that varies as a function of the RC time constant of the first sensing device;
a second oscillator configured to output a second oscillator signal having a frequency that varies as a function of the RC time constant of the second sensing device; and
the evaluation circuit is configured to compare the frequency of the first oscillator signal and the frequency of the second oscillator signal.

16. The integrated circuit of claim 15, wherein the third sensing device comprises a third resistor-capacitor circuit comprising a third resistor and a third capacitor, and
wherein the integrated circuit further comprises a third oscillator configured to output a third oscillator signal having a frequency that varies as a function of the RC time constant of the third sensing device.

17. The integrated circuit of claim 4, further comprising:
a stress compensation circuit and the plurality of electronic components comprise at least one of the following circuits:
a bandgap voltage reference circuit, an oscillator circuit, or a Hall effect sensor circuit,
wherein the stress compensation circuit is configured to reduce a mechanical stress dependency for the at least one circuit based on at least one output of the evaluation circuit.

18. The integrated circuit of claim 4, further comprising:
a stress compensation circuit configured to derive a correction factor for correcting a parameter of at least one of the electronic components based on at least one output of the evaluation circuit.

19. The integrated circuit of claim 18, wherein the stress compensation circuit is further configured to apply the correction factor to a circuit of at least one of the electronic components to reduce an effect of mechanical stress on the circuit of the electronic component.

20. The integrated circuit of claim 7, wherein the evaluation circuit is configured to:
derive a first evaluation signal proportional to the difference between a first normal in plane mechanical stress component acting on the integrated circuit and a second normal in plane mechanical stress component acting on the integrated circuit; and
derive a second evaluation signal proportional to a sum of the first normal in plane mechanical stress component and the second normal in plane mechanical stress component.

21. The integrated circuit of claim 1, wherein a thickness of each of the metal interconnect layers of the plurality of metal interconnect layers is less than 1 micrometer and/or a thickness of a dielectric layer between a first metal interconnect layer of the plurality of metal interconnect layers and a second metal interconnect layer of the plurality of metal interconnect layers is less than 1 micrometer.

22. The integrated circuit of claim 1, wherein the plurality of electronic components comprises a plurality of Fin field effect transistors (FinFETs) having process nodes equal to or less than 28 nm.

23. A method of manufacturing an integrated circuit, the method comprising:
providing a semiconductor substrate; and
forming a plurality of metal interconnect layers on the substrate including a first metal interconnect layer, wherein forming the metal interconnect layers comprises forming a sensing arrangement adapted to provide an output signal comprising a component proportional to a change in mechanical stress applied to the integrated circuit, wherein forming the sensing arrangement comprises forming a first sensing device in the first metal interconnect layer wherein the first sensing device is arranged to produce a change in an electronic property of the first sensing device in response to a change in mechanical stress applied to the integrated circuit.

24. The method of claim 23, further comprising:
forming a second sensing device in the plurality of metal interconnect layers wherein the second sensing device is arranged to produce a change in an electronic property of the second sensing device in response to a change in mechanical stress applied to the integrated circuit; and
integrating an evaluation circuit configured to determine a first signal, wherein the first signal varies with:
(i) a difference between the electronic property of the first sensing device and the electronic property of the second sensing device, or
(ii) a ratio of the electronic property of the first sensing device and the electronic property of the second sensing device.

25. The method of claim 24, wherein each of the first sensing device and the second sensing device comprises:
a capacitor, wherein the electronic property is capacitance; or
a resistor, wherein the electronic property is resistance; or
a resistor-capacitor circuit, wherein the electronic property comprises RC time constant of the resistor-capacitor circuit.

26. The method of claim 24, further comprising:
forming a third sensing device arranged to produce a change in an electronic property of the first sensing device in response to a change in mechanical stress applied to the integrated circuit.

27. The method of claim 26, further comprising:
forming a plurality of vias connecting the metal interconnect layers and wherein the third sensing device is formed in the plurality of metal interconnect layers and the plurality of vias.

28. The method of claim 26 further comprising:
integrating a stress compensation circuit; and
integrating at least one of a bandgap voltage reference circuit, an oscillator circuit, or a Hall effect sensor circuit,
wherein the stress compensation circuit is configured to reduce a mechanical stress dependency for the bandgap voltage reference circuit, the oscillator circuit, or the Hall effect sensor circuit.

29. The method of claim 28, wherein the stress compensation circuit is configured to derive a correction factor for correcting a parameter of at least one electronic component based on the first signal and the second signal.

30. The method of claim 29, wherein the at least one electronic component comprises a plurality of Fin field effect transistors (FinFETs) having process nodes equal to or less than 28 nm.
